(19) United States
(12) Patent Application Publication
(10) Pub. No.: US 2011/0316119 A1
(43) Pub. Date: Dec. 29, 2011

(54) SEMICONDUCTOR PACKAGE HAVING DE-COUPLING CAPACITOR

(76) Inventors: Yong-hoon KIM, Suwon-si (KR); Yeong-jun Cho, Seoul (KR); Ji-hyun Lee, Seoul (KR); Hee-seok Lee, Yongin-si (KR)

(21) Appl. No.: 13/168,111

(22) Filed: Jun. 24, 2011

(30) Foreign Application Priority Data
Jun. 24, 2010 (KR) 10-2010-0060133

(51) Int. Cl. H01L 23/485

(52) U.S. Cl. 257/532; 257/E23.021

(57) ABSTRACT

Provided is a semiconductor package including a de-coupling capacitor. The semiconductor package includes a substrate, on an upper surface of which a semiconductor chip is mounted; a plurality of first conductive bumps that are disposed on a lower surface of the substrate and that electrically connect the substrate to an external device; and a de-coupling capacitor that is disposed on the lower surface of the substrate and includes an electrode portion and at least one dielectric layer, wherein the electrode portion of the de-coupling capacitor includes second conductive bumps that electrically connect the substrate to an external device.

### CROSS-REFERENCE TO RELATED APPLICATIONS

This application claims priority under 35 USC §119 to Korean Patent Application No. 10-2010-0060133, filed on Jun. 24, 2010, in the Korean Intellectual Property Office (KIPO), the disclosure of which is incorporated herein in its entirety by reference.

### BACKGROUND

1. Field

The inventive concepts relate to a semiconductor package, and more particularly, to a de-coupling capacitor formed in a semiconductor device and a semiconductor package including the de-coupling capacitor.

2. Background

In line with the trend of high integration of electronic systems, an integration degree of a semiconductor package mounted in a system is continuously increasing. Accordingly, in order to obtain a higher integration degree per unit surface area, a package in which a semiconductor device is vertically stacked and that uses a wire and solder ball bonding is widely used instead of a conventional two-dimensional plane structure.

### SUMMARY

The inventive concepts provide a de-coupling capacitor and a semiconductor package including the de-coupling capacitor.

In accordance with an example embodiment of the inventive concepts, a semiconductor package may include a first substrate having an upper surface upon which at least one semiconductor chip is mounted, a plurality of first conductive bumps on a lower surface of the first substrate, and a de-coupling capacitor on the lower surface of the first substrate. In this example embodiment the plurality of first conductive bumps may be configured to electrically connect the first substrate to an external device. In addition, the de-coupling capacitor may include an electrode portion and at least one dielectric layer and the electrode portion may include second conductive bumps configured to electrically connect the first substrate to the external device.

In accordance with an example embodiment of the inventive concepts, a de-coupling capacitor may include a plurality of conductive bumps configured to attach to a lower surface of a substrate and a dielectric layer between the plurality of conductive bumps.

In accordance with an example embodiment of the inventive concepts, a package on package (POP) may include upper and lower semiconductor packages each comprising a substrate having an upper surface on which at least one semiconductor chip is mounted and a lower surface upon which a plurality of conductive bumps are disposed. In this example embodiment, the POP further includes a de-coupling capacitor on the lower surface of the substrate of the upper semiconductor package, the de-coupling capacitor including an electrode portion and a dielectric layer. In this example embodiment the plurality of conductive bumps on the lower surface of the lower package may be configured to electrically connect to an external device, and the electrode portion of the de-coupling capacitor may include a plurality of conductive pads connecting to at least one of signal lines and ground lines in the substrates of the upper and lower semiconductor packages.

In accordance with an example embodiment of the inventive concepts, a package on package may include a first substrate, a second substrate on the first substrate, and a decoupling capacitor between the first and second substrates. In this example embodiment the first substrate may have an upper surface upon which at least one first semiconductor chip is mounted and a lower surface upon which at least one first solder ball is attached. The second substrate may include an upper surface upon which at least one second semiconductor chip is mounted and a lower surface upon which at least one second solder ball is attached and the at least one second solder ball may be configured to electrically connect the first substrate to the second substrate. In this example embodiment the decoupling capacitor may include an electrode portion and a dielectric layer, wherein the electrode portion includes conductive structures connected to at least one of ground lines and signal lines in the first and second substrates.

According to an aspect of the inventive concepts, there is provided a semiconductor package comprising: a substrate, on an upper surface of which a semiconductor chip is mounted; a plurality of first conductive bumps that are disposed on a lower surface of the substrate and that electrically connect the substrate to an external device; and a de-coupling capacitor that is disposed on the lower surface of the substrate and includes an electrode portion and at least one dielectric layer, wherein the electrode portion of the de-coupling capacitor includes second conductive bumps that electrically connect the substrate to an external device.

The plurality of first conductive bumps may be solder balls.

The semiconductor package may be a flip chip package.

The semiconductor package may further comprise a conductive wire that electrically connects the semiconductor chip and the substrate.

An average wiring path between the electrode portion of the de-coupling capacitor and the semiconductor chip may be shorter than an average wiring path between the first conductive bumps and the semiconductor chip.

The electrode portion of the de-coupling capacitor may comprise two second conductive bumps disposed at two sides of the decoupling capacitor.

The electrode portion of the de-coupling capacitor may further comprise the second conductive bumps and a conductive layer contacting the second conductive bumps.

The at least one dielectric layer may comprise a plurality of the dielectric layers, and the de-coupling capacitor may further comprise a conductive layer disposed between the plurality of the dielectric layers.

The de-coupling capacitor may be a multi-layer ceramic capacitor (MLCC).

The first and second conductive bumps may be each formed of at least one selected from the group consisting of a metal, a metal alloy, a conductive metal oxide, a conductive polymer material, and a conductive complex material each selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

The semiconductor package may comprise a package on package (POP) including at least two semiconductor packages that are stacked, wherein an upper semiconductor package and a lower semiconductor package are connected to each other via the first and second conductive bumps.

The electrode portion of the de-coupling capacitor may comprise the second conductive bumps disposed between the semiconductor packages.

The electrode portion of the de-coupling capacitor may comprise the second conductive bumps formed at a lower surface of the substrate of the lower semiconductor package.

The semiconductor package may further comprise a printed circuit board (PCB) to which the first and second conductive bumps are connected.

The second conductive bumps may be each connected to a power line for power connection of the PCB and a ground line for ground connection of the PCB.

According to another aspect of the inventive concepts, there is provided a de-coupling capacitor comprising: a plurality of conductive bumps formed on a lower surface of a substrate; and a dielectric layer formed between the plurality of conductive bumps.

According to another aspect of the inventive concepts, there is provided a package on package (POP) comprising: upper and lower semiconductor packages each comprising a substrate, on an upper surface of which a semiconductor chip is mounted, and a plurality of conductive bumps that are disposed on a lower surface of the substrate and that electrically connect the substrate to an external device; and a de-coupling capacitor that is disposed on a lower surface of the substrate of the upper semiconductor package and comprises an electrode portion and a dielectric layer, wherein the electrode portion of the de-coupling capacitor comprises a plurality of conductive pads that are to be connected to signal lines in the substrates of the upper and lower semiconductor packages.

The electrode portion of the de-coupling capacitor may comprise two conductive pads respectively disposed on and under the dielectric layer.

The conductive pads of the de-coupling capacitor may be each connected to a power line for power connection in the substrate of the upper semiconductor package and a ground line for ground connection in the substrate of the lower semiconductor package.

The conductive pads of the de-coupling capacitor may be each connected to a ground line for ground connection in the substrate of the upper semiconductor package and a power line for power connection in the substrate of the lower semiconductor package.

### BRIEF DESCRIPTION OF THE DRAWINGS

Example embodiments of the inventive concepts will be more clearly understood from the following detailed description taken in conjunction with the accompanying drawings in which:

FIG. 1 is a cross-sectional view illustrating a semiconductor package including a de-coupling capacitor according to an example embodiment of the inventive concepts;

FIGS. 2A through 2C are cross-sectional views illustrating de-coupling capacitors according to an example embodiment of the inventive concepts;

FIG. 3 is a cross-sectional view illustrating a semiconductor package including a de-coupling capacitor according to another example embodiment of the inventive concepts;

FIG. 4 is a cross-sectional view illustrating a semiconductor package including a de-coupling capacitor according to another example embodiment of the inventive concepts;

FIG. 5 is a cross-sectional view illustrating a semiconductor package on package including a de-coupling capacitor according to an example embodiment of the inventive concepts;

FIG. 6 is a cross-sectional view illustrating a semiconductor package on package including a de-coupling capacitor according to another example embodiment of the inventive concepts;

FIG. 7 is a cross-sectional view illustrating a semiconductor package on package including a de-coupling capacitor according to another example embodiment of the inventive concepts;

FIGS. 8A through 8F are cross-sectional views illustrating a method of manufacturing the semiconductor package on package including the de-coupling capacitor of FIG. 6, according to an example embodiment of the inventive concepts;

FIG. 9 is a cross-sectional view illustrating a semiconductor package on package including a de-coupling capacitor according to another example embodiment of the inventive concepts;

FIG. 10 is a cross-sectional view illustrating a semiconductor package including a de-coupling capacitor according to another example embodiment of the inventive concepts;

FIG. 11 is a cross-sectional view illustrating a semiconductor package including a de-coupling capacitor according to another example embodiment of the inventive concepts;

FIG. 12 is a schematic circuit diagram illustrating a semiconductor package including a de-coupling capacitor according to an example embodiment of the inventive concepts; and

FIG. 13 is a graph illustrating simulation results of impedance of a semiconductor package including a de-coupling capacitor, according to frequencies.

### DETAILED DESCRIPTION OF THE EXAMPLE EMBODIMENTS

The invention will now be described more fully with reference to the accompanying drawings, in which example embodiments of the invention are shown.

The example embodiments are provided so that this disclosure will be thorough and complete, and will fully convey the concepts of the invention to those skilled in the art. The invention may be embodied in many different forms and should not be construed as being limited to the example embodiments set forth herein; rather, these example embodiments are provided so that this disclosure will be thorough and complete, and will fully convey the concepts of the invention to those skilled in the art.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. Like numbers refer to like elements throughout. As used herein, the term “and/or” includes any and all combinations of one or more of the associated listed items.

The terminology used herein is for the purpose of describing particular example embodiments only and is not intended to be limiting of example embodiments. As used herein, the singular forms “a,” “an” and “the” are intended to include the plural foams as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In the present description, terms such as ‘first’, ‘second’, etc. are used to describe various members, components, regions, layers, and/or portions. However, it is obvious that the members, components, regions, layers, and/or portions should not be defined by these terms. The terms are used only for distinguishing one member, component, region, layer, or portion from another member, component, region, layer, or portion. Thus, a first member, component, region, layer, or portion which will be described may also refer to a second member, component, region, layer, or portion, without departing from the teaching of the present invention.

Example embodiments of the inventive concepts are described herein with reference to cross-section illustrations that are schematic illustrations of idealized example embodiments of the inventive concepts. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing.

High speed operations of a semiconductor device in a package may be limited in various ways, such as by noise, signal delay, or the like. In addition, the number of signals simultaneously transmitted to a semiconductor device, as well as a signal speed, is significantly increasing. In combination with parasitic inductance components of a substrate of a semiconductor device, for example, a semiconductor package, the signals may appear as power and ground noise. Power and ground noise increases the higher an operation speed of a semiconductor device and the higher the number of simultaneously transmitted signals, and thus acts as a serious hindrance for high speed operations of a semiconductor device. To solve the problem of power and ground noise, widely used methods include a method of designing a power and ground path to have low inductance and a method of forming a de-coupling capacitor on a surface of a substrate to stabilize power and ground.

When forming a de-coupling capacitor in a semiconductor device, resistance and inductance thereof may ideally be 0, but internal resistance and inductance components, that is, equivalent series resistor (ESR) and equivalent series inductance (ESL) problems in a conduction path between the semiconductor device and the de-coupling capacitor and in the de-coupling capacitor itself, are present. Thus stabilization of power and ground by using the de-coupling capacitor is important.

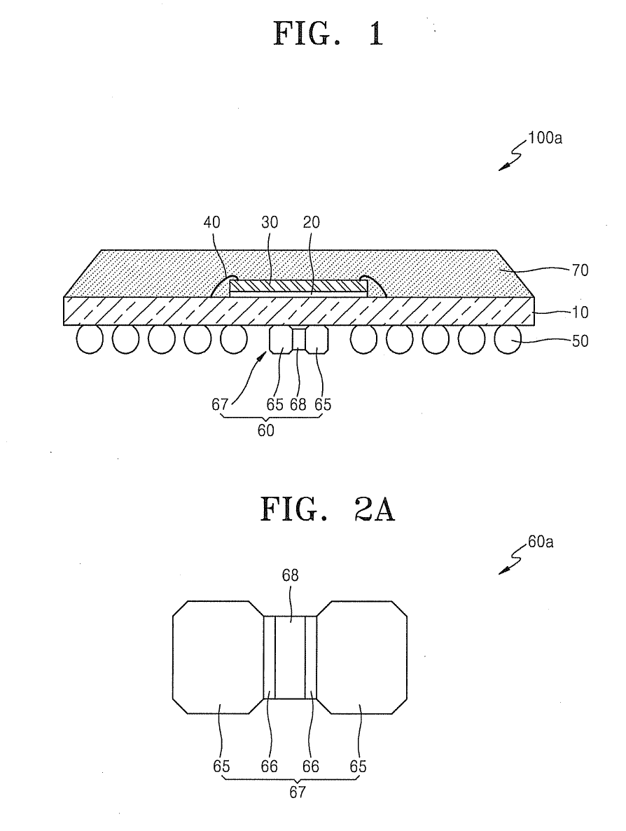

FIG. 1 is a cross-sectional view illustrating a semiconductor package 100a including a de-coupling capacitor according to an example embodiment of the inventive concepts.

Referring to FIG. 1, in the semiconductor package 100a, a semiconductor chip 30 is mounted on an adhesive layer 20 that is formed of an adhesive material and formed on a substrate 10, and a semiconductor device (not shown) in the semiconductor chip 30 is electrically connected to the substrate 10 via a conductive wire 40. The conductive wire 40 is connected to a wiring formed in the substrate 10 and conductive bumps 50 and 65, formed on a lower surface of the substrate 10 via the wiring to be connected to various power sources, signal sources, and ground terminals of a system in which the semiconductor package 100a is mounted. A vertical via, (not shown) is formed in the semiconductor chip 30 and the semiconductor chip 30 also may be electrically connected to the substrate 10 via the vertical via. The conductive bumps 50 and 65 are disposed on the lower surface of the substrate 10 so that the substrate 10 and an external device, such as a printed circuit board, may be electrically connected to each other. The conductive bumps 50 and 65 may be first conductive bumps 50 and second conductive bumps 65. A de-coupling capacitor 60 that uses the second conductive bumps 65 as electrode portions 67 is disposed on the lower surface of the substrate 10.

The substrate 10 may be formed of an epoxy resin, a polyimide resin, bismaleimide triazine (BT) resin, a flame retardant 4 (FR-4), an FR-5, a ceramic, a silicon, or a glass, but is not limited thereto. The substrate 10 may be a single layer or a multi-layer structure including wiring patterns. For example, the substrate 10 may be a rigid flat substrate, a plurality of rigid flat substrates that are adhered to one another, or flexible PCB and the rigid flat substrate that are adhered to each other. The plurality of rigid flat substrates adhered to one another or the PCBs may each include wiring patterns. Also, the substrate 10 may be a low temperature co-fired ceramic (LTCC) substrate. The LTCC substrate may be formed of a plurality of stacked ceramic layers, and wiring patterns may be included in the LTCC substrate. A plated through hole (PTH) and/or a blind via hole (BVH) may be fanned in the substrate 10 to electrically connect an upper surface of the substrate 10 and the lower surface of the substrate 10.

The semiconductor chip 30 may have a structure that includes a semiconductor device (not shown) formed on a semiconductor substrate (not shown). The semiconductor substrate (not shown) may be a silicon substrate, but the inventive concepts are not limited thereto. Alternatively, the semiconductor substrate (not shown) may be a silicon on insulator (SOI) substrate. The semiconductor device (not shown) may be a flash device such as a dynamic random access memory (DRAM) device, a static random access memory (SRAM) device, a phase-change random access memory (PRAM) device, or a flash memory device, or a non-memory device such as a logic device. In detail, the semiconductor device may include transistors, resistors, and wirings, and the semiconductor chip 30 may include conductive pads that are exposed and that may be electrically connected to an outside element. A plurality of the semiconductor chips 30 may be stacked, and be electrically connected to one another using a through silicon via (TSV) technique. The semiconductor chip 30 may be connected to a wiring of the substrate 10 via the pads and the conductive wire 40, and may be electrically connected to the second conductive bumps 65 constituting the electrode portions 67 of the de-coupling capacitor 60. Example embodiments of the inventive concepts, however, are not limited hereto. For example, a plurality of the semiconductor chips 30 may be stacked, and may be electrically connected to one another using a wire bonding technique or a combination of through silicon vias and wires. As described previously, the plurality of semiconductor chips 30 that may be stacked and connected to each other via wires may be connected to a wiring of the substrate 10 via the pads and the conductive wire 40, and may be electrically connected to the second conductive bumps 65 constituting the electrode portions 67 of the de-coupling capacitor 60.

The first and second conductive bumps 50 and 65 are formed on the lower surface of the substrate 10 so that the semiconductor package 100a may be mounted on an external PCB using, for example, a ball grid array (BGA) method, and may transmit/receive electrical signals via the first conductive bumps 50. The first conductive bumps 50 may be formed of at least one selected from the group consisting of a metal, a metal alloy, a conductive metal oxide, a conductive polymer material, and a conductive complex material each formed of at least one selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C). The first and second conductive bumps 50 and 65 are electrically connected to the wiring of the substrate 10 and may perform similar functions of forming an electrical connection to an external device (not shown).

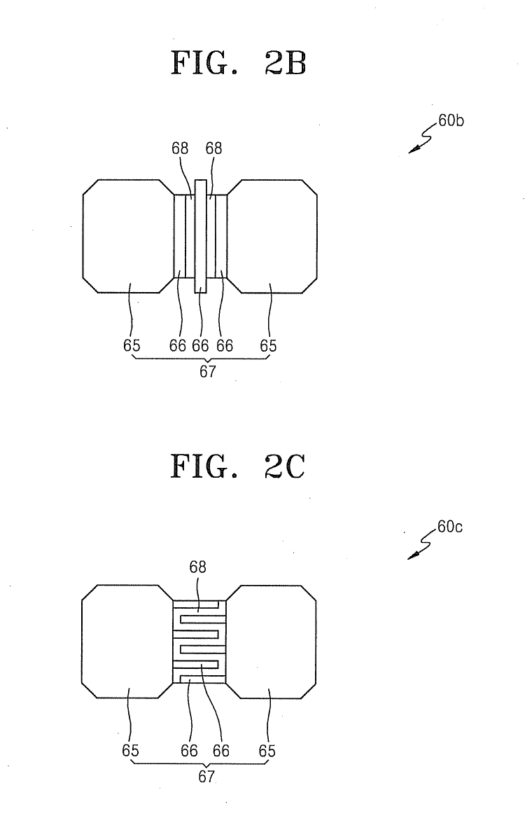

The de-coupling capacitor 60 is formed on the lower surface of the substrate 10, and may include the electrode portions 67 formed at two sides thereof and a dielectric layer 68 formed between the electrode portions 67. The electrode portions 67 of the de-coupling capacitor 60 may be the second conductive bumps 65 or another conductive layer (not shown) that is disposed in such a way that a portion thereof contacts the second conductive bumps 65. The structure of the de-coupling capacitor 60 will be described in detail with reference to FIGS. 2A through 2C. The de-coupling capacitor 60 is electrically connected to the substrate 10 via the second conductive bumps 65 constituting the electrode portions 67, and may thus be electrically connected to the semiconductor chip 30. That is, the second bumps 65 may be the electrode portions 67 of the de-coupling capacitor 60, and may perform the same function as that of the first conductive bumps 50 at the same time.

The de-coupling capacitor 60 may be disposed on the lower surface of the substrate 10 nearest to the semiconductor chip 30 so that a wiring path connecting the semiconductor chip 30 and the de-coupling capacitor 60 may be as short as possible. Accordingly, an average wiring path between the electrode portions 67 of the de-coupling capacitor 60 and the semiconductor chip 30 may be shorter than an average wiring path between the first conductive bumps 50 and the semiconductor chip 30. The average wiring path refers to an average of wiring paths between two of any first conductive bumps 50 or two of any second conductive bumps 65 and the semiconductor chip 30. The de-coupling capacitor 60 supplements a current supply if a large current is suddenly required in the semiconductor chip 30 to prevent or reduce a voltage drop, and may remove or reduce noise generated by a high frequency signal generation source of peripheral circuits.

A molding portion 70 is formed on the semiconductor chip 30 and may cover the entire surface of the substrate 10 as shown in FIG. 1. The molding portion 70 may be formed of an epoxy molding compound (EMC). The EMC is epoxy resin and a thermosetting resin encapsulation material that protects the semiconductor chip 30 from heat, water, and an outside impact.

FIGS. 2A through 2C are cross-sectional views illustrating de-coupling capacitors 60a, 60b, and 60c according to example embodiments of the inventive concepts.

The de-coupling capacitors 60a, 60b, and 60c may each include the electrode portions 67 at two sides thereof and the dielectric layer 68 formed between the electrode portions 67. The dielectric layer 68 of the de-coupling capacitors 60a, 60b, and 60c may include a ferroelectric material or a paraelectric material. The dielectric layer 68 may be formed of a material including a barium titanium oxide (BaTiO₃) or a strontium titanium oxide (SrTiO₃). Also, the dielectric layer 68 may be formed of a pressurized dielectric sheet, and the de-coupling capacitors 60a, 60b, and 60c may be multi-layer ceramic capacitors (MLCCs).

Referring to FIG. 2A, the electrode portions 67 of the de-coupling capacitor 60a may include the second conductive bumps 65, and may also include conductive layers 66 disposed in such a way that portions thereof are disposed between the second conductive bumps 65 and the dielectric layer 68. Accordingly, the electrostatic capacitance of the de-coupling capacitor 60a may be adjusted by adjusting a thickness of the dielectric layer 68.

Referring to FIG. 2B, the de-coupling capacitors 60b may have a multi-layer structure having an electrostatic capacitance that is increased by stacking at least two metal-insulator-metal (MIM) structures. That is, a plurality of the conductive layers 66 and a plurality of the dielectric layers 68 between the conductive layers 66 may be arranged alternately. Although FIG. 2B shows an example embodiment that includes three conductive layers 66 and two dielectric layers 68, example embodiments of the inventive concepts are not limited thereto as there could be more than three conductive layers 66 separated by more than two dielectric layers 68.

Referring to FIG. 2C, the de-coupling capacitor 60c may have a structure in which the electrode portions 67 includes the second conductive bumps 65 and a plurality of the conductive layers 66, and the conductive layers 66 are disposed between the dielectric layers 68, and sides of the conductive layers 66 contact the second conductive bumps 65. The form of the conductive layers 66 is not limited to as illustrated and may be various.

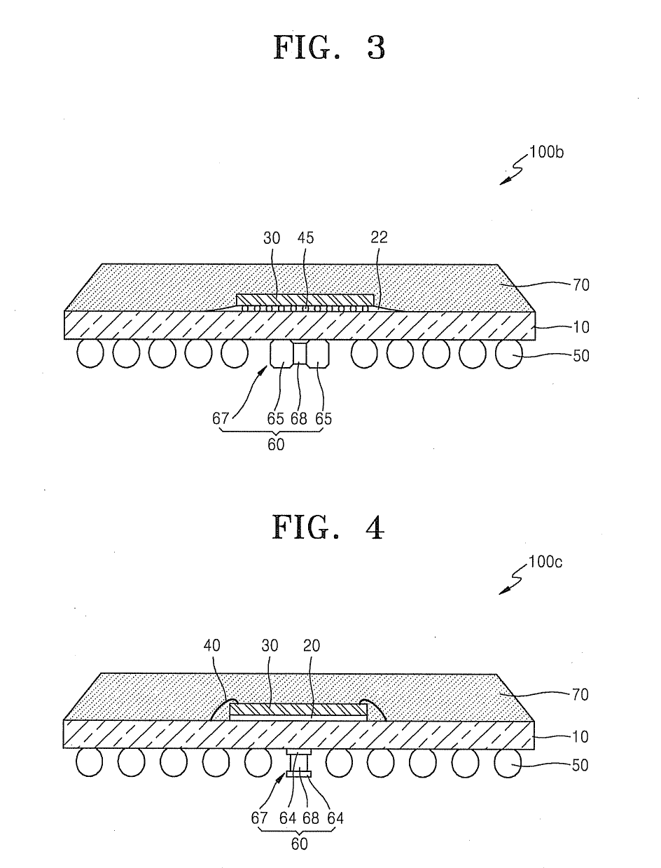

FIG. 3 is a cross-sectional view illustrating a semiconductor package 100b including a de-coupling capacitor according to another example embodiment of the inventive concepts.

Reference numerals in FIG. 3 that are the same as reference numerals in FIG. 1 denote like elements, and thus the descriptions of the like elements will be omitted here. Referring to FIG. 3, the semiconductor package 100b is a flip-chip package 100b. In the flip-chip package 100b, a plurality of third conductive bumps 45 disposed on a lower surface of the semiconductor chip 30 are used to connect the semiconductor chip 30 and the substrate 10 or the semiconductor chip 30 is directly connected to a connection terminal of the substrate 10. A conductive pad (not shown) may be formed between the third conductive bumps 45 and the semiconductor chip 30. An underfill layer 22 may be formed by implanting a liquid resin-type underfill material in a gap between the semiconductor chip 30 and the substrate 10 and between the third conductive bumps 45 and hardening the underfill material. In FIG. 3, a first surface of the semiconductor chip 30 may be disposed to face the substrate 10. Accordingly, a second surface of the semiconductor chip 30 may be disposed facing in a direction away from the substrate 10. Also, in the flip-chip package 100b, the de-coupling capacitor 60 may be disposed on the lower surface of the substrate 10, and the electrode portions 67 of the de-coupling capacitor 60 are formed of the second conductive bumps 65.

FIG. 4 is a cross-sectional view illustrating a semiconductor package 100c including a de-coupling capacitor according to another example embodiment of the inventive concepts.

Reference numerals in FIG. 4 that are the same as reference numerals FIGS. 1 and 3 denote like elements, and thus the descriptions of the like elements will be omitted here. Referring to FIG. 4, the de-coupling capacitor 60 is disposed at one of positions in which one of the first conductive bumps 50 may be arranged, and conductive pads 64 constituting the electrode portions 67 of the de-coupling capacitor 60 are respectively formed on and under the dielectric layer 68 in a direction perpendicular to the substrate 10. The conductive pads 64 may be formed of at least one selected from the group consisting of a metal, a metal alloy, a conductive metal oxide, a conductive polymer material, and a conductive complex material each formed of at least one selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C). The conductive pad 64 formed on the dielectric layer 68 may be electrically connected to the substrate 10, and the conductive pad 64 formed under the dielectric layer 68 may be electrically connected to an external device (not shown). For example, the conductive pad 64 formed on the dielectric layer 68 may be connected to an external device (not shown) such as a PCB via any first conductive bump 50 along a power line (not shown) for power connection in the substrate 10. The conductive pad 64 formed under the dielectric layer 68 may be directly connected to an external device (not shown). In the semiconductor package 100c according to the current example embodiment, two conductive pads 64 constituting the electrode portions 67 of the de-coupling capacitor 60 allows the de-coupling capacitor 60 to be connected to the substrate 10 and an external device (not shown).

Compared to the example embodiments of FIGS. 1 and 3, in the current example embodiment of FIG. 4, the electrode portions 67 of the de-coupling capacitor 60 are electrically connected to the semiconductor chip 30 formed on the substrate 10 and an external device (not shown) via the conductive pads 64 that are respectively connected to the substrate 10 and the external device (not shown). According to the semiconductor package 100c according to the current embodiment, a surface area for mounting the de-coupling capacitor 60 is reduced, and the de-coupling capacitor 60 is disposed near the semiconductor chip 30, thereby reducing or eliminating simultaneous switching noise (SSN).

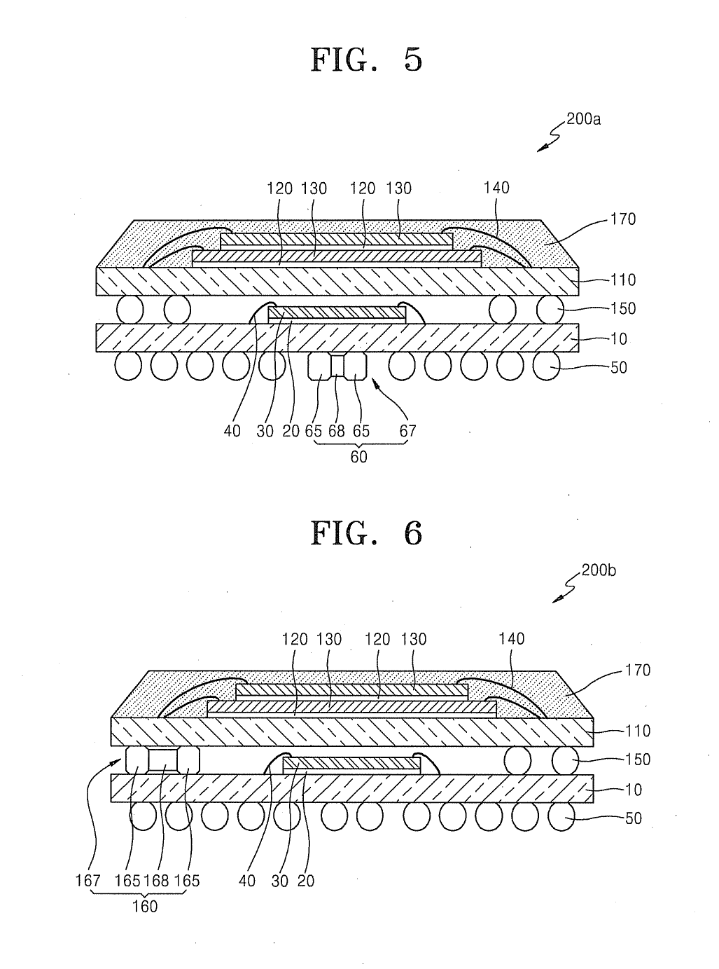

FIG. 5 is a cross-sectional view illustrating a semiconductor package on package 200a including a de-coupling capacitor according to an example embodiment of the inventive concepts.

According to demands for high performance and miniaturization of electronic components, a package on package (POP) structure in which a plurality of package substrates are stacked to form one package is used to implement a high density package. Referring to FIG. 5, the package on package 200a has a structure in which an upper semiconductor package is stacked on a lower semiconductor package. The lower semiconductor package has a structure similar to that of the semiconductor package illustrated in FIG. 1, and thus descriptions thereof will not be repeated. The upper semiconductor package may include an adhesive layer 120 formed on a substrate 110 and a semiconductor chip 130 formed on the adhesive layer 120. The upper semiconductor package may have a structure in which at least two semiconductor chips 130 are stacked and the lower semiconductor package may have a structure in which two or more of the semiconductor chips 30 are stacked, and in this case, semiconductor devices (not shown) of the semiconductor chips 30 and 130 may be respectively electrically connected to the substrates 10 and 110 by the conductive wire 40 and a conductive wire 140. Also, although not illustrated in FIG. 5, the semiconductor devices (not shown) in the semiconductor chips 30 and 130 may be respectively connected to the substrate 10 and 110 through vias formed in the semiconductor chips 30 and 130. The lower semiconductor package and the upper semiconductor package are electrically connected to each other via conductive bumps 150 formed there between. The de-coupling capacitor 60 according to the current example embodiment may be disposed on a lower surface of the lower semiconductor package of the package on package 200a.

FIG. 6 is a cross-sectional view illustrating a semiconductor package on package 200b including a de-coupling capacitor according to another example embodiment of the inventive concepts.

Reference numerals in FIG. 6 that are the same as reference numerals in FIG. 5 denote like elements, and thus descriptions of the like elements will be omitted. Referring to FIG. 6, a de-coupling capacitor 160 is disposed between a lower semiconductor package and an upper semiconductor package of the package on package 200b. The upper and lower semiconductor packages of the package on package 200b are electrically connected to each other via the conductive bumps 150 and conductive bumps 165, herein first and second conductive bumps, disposed on a lower surface of the upper semiconductor package. The de-coupling capacitor 160 may be disposed at a side of the semiconductor chip 30 of the lower semiconductor package by using the second conductive bumps 165 disposed on a lower surface of the substrate 110 as electrode portions 167. According to the current example embodiment, the de-coupling capacitor 160 may be disposed adjacent to all of the semiconductor chips 30 and 130 respectively mounted in the upper and lower packages, thereby efficiently removing noise generated by a source of high frequency signals. Like the first conductive bumps 150, the second conductive bumps 165 also allow an electrical connection between the upper and lower semiconductor packages. The de-coupling capacitor 160 may be disposed at one side of the lower semiconductor package as illustrated in FIG. 6, or at two sides thereof.

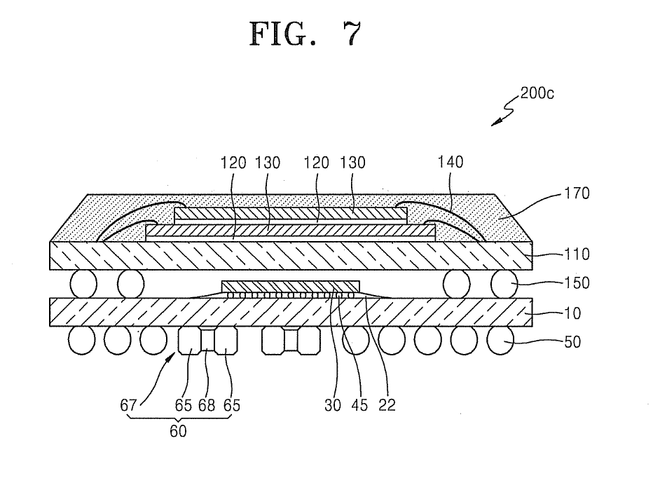

FIG. 7 is a cross-sectional view illustrating a semiconductor package on package 200c including a de-coupling capacitor according to another example embodiment of the inventive concepts.

Reference numerals in FIG. 7 that are the same as reference numerals in FIGS. 5 and 6 denote like elements, and thus descriptions of the like elements will be omitted. Referring to FIG. 7, a lower semiconductor package of the package on package 200c is a flip-chip package having the structure that has been described with reference to FIG. 3. The de-coupling capacitor 60 in the package on package 200c is disposed on the lower surface of substrate 10 of the lower semiconductor package, and at least two of the de-coupling capacitors 60 may be disposed. The de-coupling capacitors 60 may be disposed adjacent to semiconductor chips 30 and 130 mounted in the package on package 200c, and at least two of the de-coupling capacitors 60 may be arranged parallel to each other. In FIG. 7, the two de-coupling capacitors 60 are mounted on the lower surface of the substrate 10 of the lower semiconductor package, but example embodiments of the inventive concepts are not limited thereto; for example, the two de-coupling capacitors 60 may be mounted on the lower surface of the substrate 110 of the upper semiconductor package and between the upper and lower semiconductor packages.

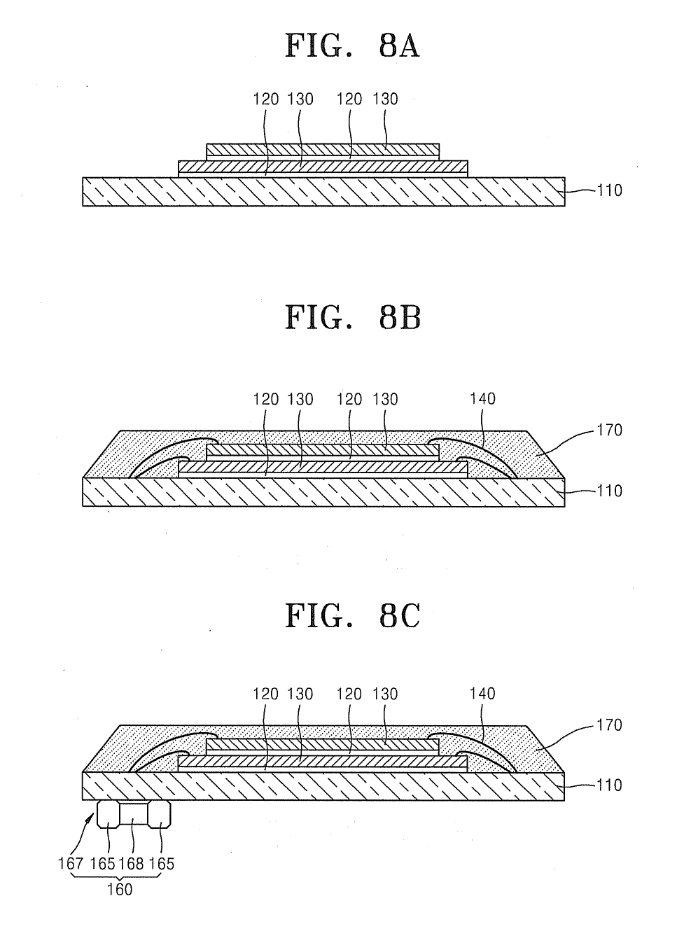

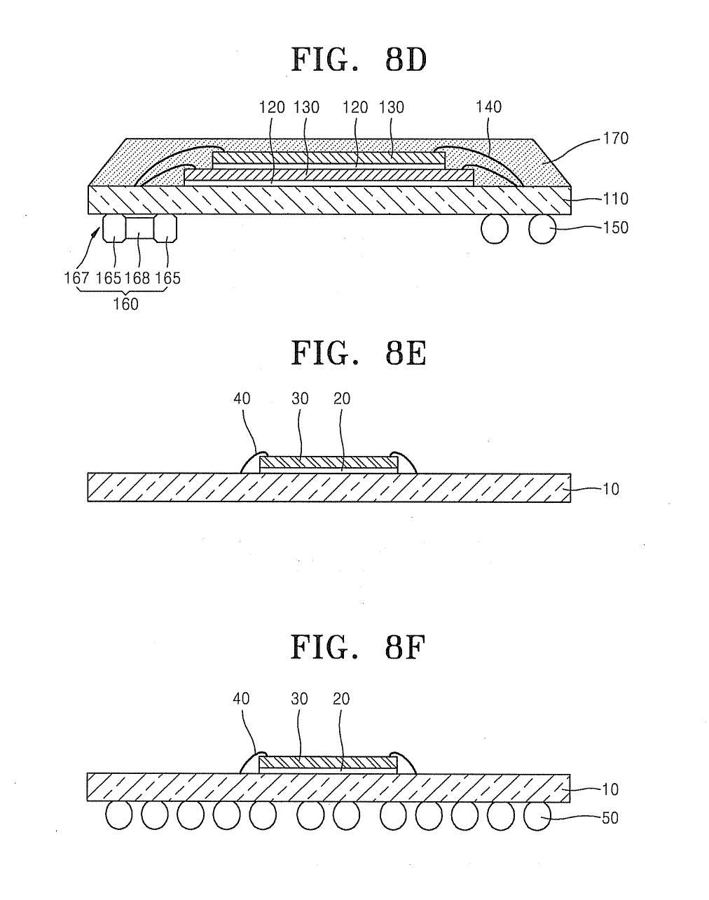

FIGS. 8A through 8F are cross-sectional views illustrating a method of manufacturing the semiconductor package on package 200b including the de-coupling capacitor 160 of FIG. 6, according to an example embodiment of the inventive concepts.

Referring to FIG. 8A, the upper semiconductor package of the package on package 200b is manufactured. The adhesive layer 120 is formed on the substrate 110, and the semiconductor chips 130 are mounted on the adhesive layer 120. At least two of the semiconductor chips 130 may be mounted, and the adhesive layer 120 may be further formed between the semiconductor chips 130 to connect the semiconductor chips 130 to each other. When bonding the semiconductor chips 130 and semiconductor devices (not shown) formed in the semiconductor chips 130 to the substrate 110 by using the conductive wire 140 in a subsequent process, the semiconductor chips 130 in upper portions may have narrower widths than the semiconductor chips 130 in lower portions in order to final bonding portions.

Referring to FIG. 8B, the semiconductor chips 130 and the semiconductor devices (not shown) formed in the semiconductor chips 130 are bonded to the substrate 110 using the conductive wire 140. Although not shown in FIG. 8B, an additional conductive pad may be formed between the conductive wire 140 and a connection portion of the substrate 110. The conductive wire 140 may be formed of at least one selected from the group consisting of a metal and a metal alloy each formed of at least one selected from the group consisting of copper (Cu), aluminum (Al), nickel (Ni), silver (Ag), and gold (Au). After bonding the conductive wire 140, the molding portion 170 is formed so as to protect the semiconductor chips 130 and the conductive wire 140.

Referring to FIG. 8C, the de-coupling capacitor 160 is formed on a portion of the lower surface of the substrate 110 of the upper semiconductor package. The portion is any portion of the lower surface of the substrate 110 except a portion corresponding to a space in which the semiconductor chip 30 of the lower semiconductor package is to be inserted, and the de-coupling capacitor 160 may be manufactured as a single device and then mounted on the substrate 110. The de-coupling capacitor 160 is formed of the electrode portions 167 including the second conductive bumps 165 foamed at two sides of the de-coupling capacitor 160 and a dielectric layer 168 formed between the electrode portions 167. A conductive pad (not shown) may be formed between the substrate 110 and the de-coupling capacitor 160, and the second conductive bumps 165 may be bonded to the conductive pad (not shown). Bonding may be performed by using heat or ultrasonic waves or by using both at the same time. As a result of the bonding, the substrate 110 and the de-coupling capacitor 160 are electrically connected to each other via the second conductive bumps 165.

Referring to FIG. 8D, the first conductive bumps 150 are bonded to the lower surface of the substrate 110 of the upper semiconductor package. The first conductive bumps 150 are bonded to any portion of the lower surface of the substrate 110 of the upper semiconductor package except a portion in which the de-coupling capacitor 160 is to be mounted and a portion corresponding to the space in which the semiconductor chip 30 of the lower semiconductor package is to be inserted. The first conductive bumps 150 may be solder balls. Like the second conductive bumps 165, the first conductive bumps 150 may be bonded to the substrate 110 using heat and/or ultrasonic waves.

Referring to FIG. 8E, the lower semiconductor package of a package on package is manufactured. Similar to the operation described with reference to FIG. 8A, the semiconductor chip 30 is mounted using the adhesive layer 20 and bonded to the substrate 10 via the conductive wire 40.

Referring to FIG. 8F, the first conductive bumps 50 are bonded to the lower surface of the substrate 10 of the lower semiconductor package. Then, by bonding the upper semiconductor package and the lower semiconductor package, the package on package 200b is manufactured. The upper and lower semiconductor packages are connected to each other by using a method of connecting the first and second conductive bumps 150 and 165 on the lower surface of the upper semiconductor package to an upper surface of the substrate 10 of the lower semiconductor package. Accordingly, the package on package 200b illustrated in FIG. 6 is formed. In the above-described manufacturing method, the de-coupling capacitor 160 is bonded to the upper semiconductor package, but the current example embodiment of the inventive concepts is not limited thereto. For example, the de-coupling capacitor 160 may be bonded to an upper portion of the substrate 10 when forming the lower semiconductor package.

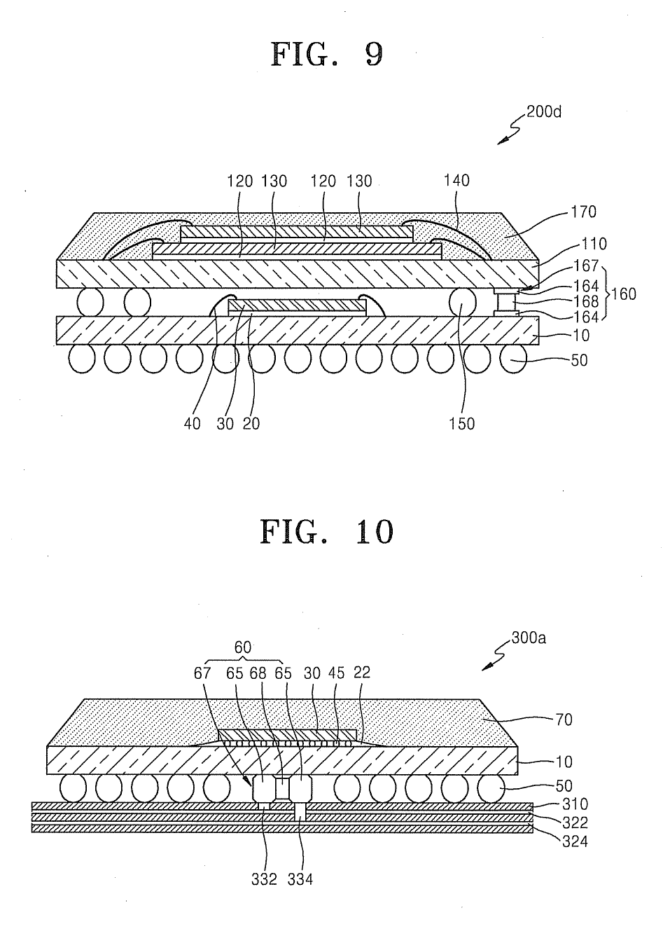

FIG. 9 is a cross-sectional view illustrating a semiconductor package on package 200d including a de-coupling capacitor according to another example embodiment of the inventive concepts.

Reference numerals in FIG. 9 that are the same as reference numerals in FIGS. 5 through 7 denote like elements, and thus descriptions of the like elements will be omitted. Referring to FIG. 9, the de-coupling capacitor 160 is disposed between a lower semiconductor package and an upper semiconductor package of the package on package 200d. In the package on package 200d, the upper and lower semiconductor packages are electrically connected to each other via the first conductive bumps 150 arranged on a lower surface of the upper semiconductor package. Similar to the semiconductor package 100c described with reference to FIG. 4, the de-coupling capacitor 160 includes the electrode portions 167 formed on and under the dielectric layer 168. The electrode portions 167 are fowled of the conductive pads 164 disposed on and under the dielectric layer 168. Accordingly, the conductive pad 164 formed above the dielectric layer 168 is electrically connected to the substrate 110 of the upper semiconductor package, and the conductive pad 164 formed under the dielectric layer 168 is connected to the substrate 10 of the lower semiconductor package, thus may be electrically connected to an external device (not shown).

FIG. 10 is a cross-sectional view illustrating a semiconductor package 300a including a de-coupling capacitor according to another example embodiment of the inventive concepts.

In general, in a semiconductor package structure, semiconductor devices in stacked semiconductor chips have three types of electric connection structures such as signal connection, power connection, and ground connection structures, and may be connected to external power sources, signal sources, and grounds via vertical vias formed through semiconductor chips, for example, a power via for power connection, a ground via for ground connection, and a signal via for signal connection. The vias may also have other forms, positions, or arrangements. If needed, other types of power vias may be separately formed, and if there are multiple signals, multiple signal vias corresponding to the number of the signals may be formed.

Referring to FIG. 10, as the semiconductor package 100b illustrated in FIG. 3 is mounted on a PCB 310 to form the semiconductor package 300a. A ground line 324 and a power line 322 may be included in the PCB 310. A semiconductor device (not shown) of the semiconductor chip 30 in the semiconductor package 300a may be connected to ground and power lines (not shown) of the substrate 10 via conductive bumps like third conductive bumps 45, a conductive wire, or a vertical via. Then again, the semiconductor device (not shown) may be connected to a ground line 324 and a power line 322 of the PCB 310 via the electrode portions 67 including the second conductive bumps 65 of the de-coupling capacitor 60 disposed on the lower surface of the substrate 10. Vertical vias 332 and 334 are formed in the PCB 310, and thus the second conductive bumps 65 may be connected to the ground line 324 and the power line 322 via the vertical vias 334 and 332, respectively a ground via and a power via. Accordingly, the electrode portions 67 of the de-coupling capacitor 60 may perform de-coupling, and transmit signals to the semiconductor chip 30 at the same time. The vertical vias 332 and 334 may be formed by boring the PCB 310 using a mechanical or chemical method and filling the same with a conductive material by, for example, plating.

The de-coupling capacitor 60 according to the current example embodiment includes two second conductive bumps 65, but the current example embodiment of the inventive concepts is not limited thereto; the de-coupling capacitor 60 may include three or more second conductive bumps 65. In this case, various de-coupling capacitors 60 may be connected serially or in parallel according to the power line 322 and the ground line 324 to which the second conductive bumps 65 are connected. For example, when three second conductive bumps 65 are included, the second conductive bump 65 in the middle is connected to the ground line 324. When the second conductive bumps 65 at two sides of the middle second conductive bump 65 are connected to the power line 322, two de-coupling capacitors 60 are formed connected in parallel, and the capacitance thereof may be adjusted accordingly.

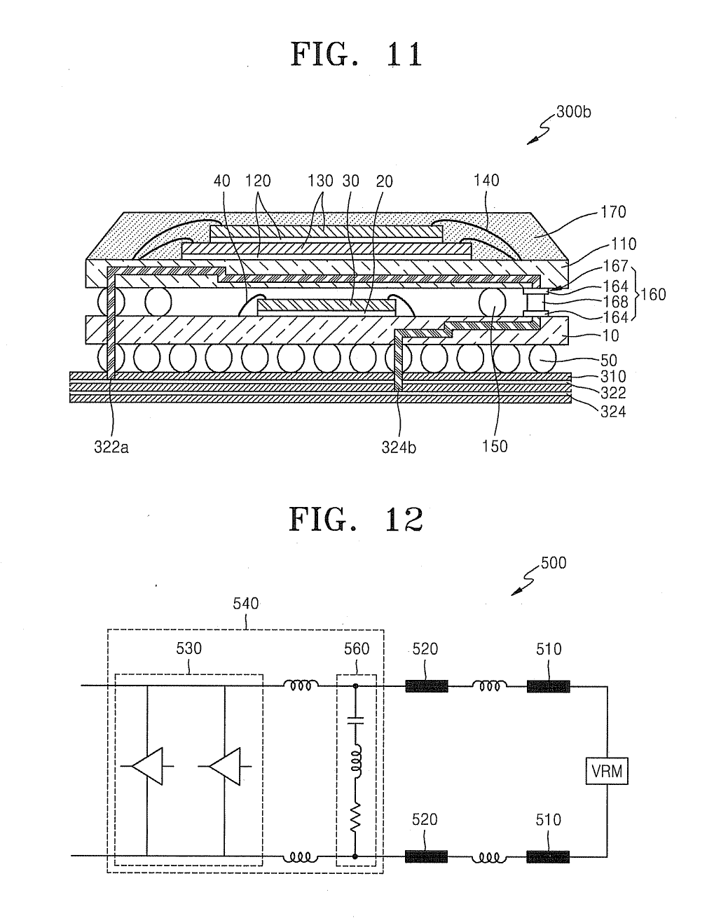

FIG. 11 is a cross-sectional view illustrating a semiconductor package 300b including a de-coupling capacitor according to another example embodiment of the inventive concepts.

Reference numerals in FIG. 11 that are the same as reference numerals in FIG. 10 denote like elements, and thus descriptions of the like elements will be omitted. Referring to FIG. 11, the semiconductor package 300b, that is, a package on package (POP), is mounted on the PCB 310. The ground line 324 and the power line 322 may be included in the PCB 310. The conductive pads 164 of the de-coupling capacitor 160 are disposed on the lower surface of the substrate 110 of the upper semiconductor package and the upper surface of the substrate 10; the conductive pad 164 formed above the dielectric layer 168 may be electrically connected to the substrate 110 of the upper semiconductor package, and the conductive pad 164 farmed under the dielectric layer 168 may be electrically connected to the PCB 310. As illustrated in FIG. 11, the conductive pad 164 farmed above the dielectric layer 168 is connected to the substrate 10 of the lower semiconductor package via any first conductive bump 150 along a power line 322a for power connection in the substrate 110, and may be connected to the power line 322 in the PCB 310 via any first conductive bump 50 disposed on the lower surface of the substrate 10 of the lower semiconductor package. The conductive pad 164 formed under the dielectric layer 168 is connected to the substrate 10 of the lower semiconductor package and is connected to the ground line 324 in the PCB 310 via any first conductive bump 50 disposed on the lower surface of the lower semiconductor package. Also, the positions of the power line 322 and the ground line 324 may be exchanged. That is, the conductive pad 164 formed above the dielectric layer 168 may connect the substrate 110 to the ground line 324 in the PCB 310 along a ground line (not shown), and the conductive pad 164 formed under the dielectric layer 168 may be connected to the power line 322 in the PCB 310 along a power line (not shown) in the substrate 10 of the lower semiconductor package. In each of the substrates 10 and 110, vertical vias (not shown) that are electrically connected to the power lines 322a and 322 and the ground lines 324b and 324 may be formed.

FIG. 12 is a schematic circuit diagram 500 illustrating a semiconductor package including a de-coupling capacitor according to an example embodiment of the inventive concepts.

Referring to FIG. 12, the circuit diagram 500 is described according to the semiconductor package 300a illustrated in FIG. 10, and the circuit diagram 500 includes a semiconductor chip 530, a de-coupling capacitor 560, and a voltage regulation module (VRM). A voltage regulator or a VRM is selected as a power source in order to provide voltage control of a predetermined level that is appropriate for most of devices. The voltage control may be performed by passing through various filter devices including passive and/or active filter devices. A voltage is applied to internal circuits of the semiconductor chip 530, and noise of the voltage may be reduced through the de-coupling capacitor 560.

A current passes through a power and/or ground (hereinafter, power/ground) network 510 of a PCB from the VRM and through a power/ground network 520 of a package substrate to be supplied to a semiconductor chip 530. An inductor on the circuit diagram 500 refers to inductance due to a wire or a conductive bump, and is formed between the power/ground network 510 of the PCB and the power/ground network 520 of the package substrate, and between the power/ground network 520 of the package substrate and the semiconductor chip 530. The de-coupling capacitor 560 has a structure in which inductance and resistance, undesired parasitic components, are connected serially, besides capacitance. The de-coupling capacitor 560 may be located not only in the semiconductor package 540 but also in the semiconductor chip 530 and on the PCB. However, according to the current example embodiment, the de-coupling capacitor 560 is located in the semiconductor package 540. Parasitic inductance components exists also on a path between the de-coupling capacitor 560 and the semiconductor chip 530, and a ratio at which the de-coupling capacitor 560 removes high frequency noise from an internal circuit of the semiconductor chip 530 is decreased proportionally to a length of the path due to the parasitic inductance components. However, when the de-coupling capacitor 560 is located in the semiconductor chip 530, a size of the semiconductor chip 530 is increased, and thus the capacitance of the de-coupling capacitor 560 is limited. Accordingly, when the de-coupling capacitor 560 is arranged in the semiconductor package 540 according to the inventive concepts, the ratio at which frequency noise is removed is maintained and the size of the semiconductor chip 530 may not be affected either.

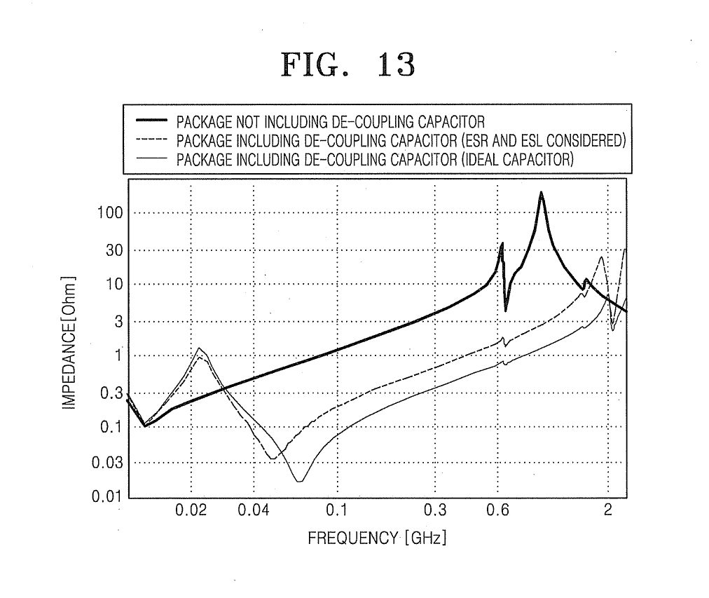

FIG. 13 is a graph illustrating simulation results of impedance of a semiconductor package including a de-coupling capacitor, according to frequencies.

Referring to FIG. 13, compared to a semiconductor package that does not include a de-coupling capacitor, an overall low impedance is generated in a semiconductor package that includes a de-coupling capacitor. In a power/ground network, preferably a minimum amount of impedance may be maintained between a power supply terminal and an end of a circuit, for example, a semiconductor chip, over all frequency bands, to prevent instantaneous change in a possible voltage and reduce noise. Results of the semiconductor package including a de-coupling capacitor illustrated in the graph of FIG. 13 are simulation results with the assumption that the de-coupling capacitor has an electrostatic capacitance of 100 nF. Here, an example of a de-coupling capacitor in consideration of ESR and ESL and an example of an ideal capacitor with no ESR or ESL are illustrated. In the semiconductor package not including a de-coupling capacitor, parallel resonance, which is generated around 0.6 GHz due to a power/ground network structure, occurs. In a range before about 0.6 GHz, impedance is likely to increase according to frequencies. In the semiconductor package including a de-coupling capacitor, an initial parallel resonance occurs by the combination of capacitance of the de-coupling capacitor and inductance of the power/ground network. Next, series resonance of the de-coupling capacitor itself is observed, and the parallel resonance of the power/ground network occurring around 0.6 GHz occurs at a frequency similar to that of the semiconductor package that does not include the above-described de-coupling capacitor. A location of the series resonance may be determined according to capacitance, position, and combination of the de-coupling capacitor. In total, a resonance peak value is reduced in a frequency band of about 0.1 GHz or greater, and thus noise is significantly reduced. In the example of an ideal de-coupling capacitor, impedance is further lowered than in the example in which ESR or ESL is considered.

While the inventive concepts have been particularly shown and described with reference to example embodiments thereof, it will be understood that various changes in form and details may be made therein without departing from the spirit and scope of the following claims.

What is claimed is:

1. A semiconductor package, comprising:
a first substrate having an upper surface upon which at least one semiconductor chip is mounted;
a plurality of first conductive bumps on a lower surface of the first substrate, the plurality of first conductive bumps configured to electrically connect the first substrate to an external device; and
a de-coupling capacitor on the lower surface of the first substrate, the de-coupling capacitor including an electrode portion and at least one dielectric layer, the electrode portion including second conductive bumps configured to electrically connect the first substrate to the external device.

2. The semiconductor package of claim 1, wherein the plurality of first conductive bumps are solder balls.

3. The semiconductor package of claim 1, wherein the at least one semiconductor chip is one of
connected to the first substrate via a plurality of third conductive bumps on a lower surface of the at least one semiconductor chip, and
directly connected to a connection terminal of the first substrate.

4. The semiconductor package of claim 1, further comprising:
at least one conductive wire electrically connecting the at least one semiconductor chip to the first substrate.

5. The semiconductor package of claim 1, wherein an average wiring path between the electrode portion of the de-coupling capacitor and the at least one semiconductor chip is shorter than an average wiring path between the first conductive bumps and the at least one semiconductor chip.

6. The semiconductor package of claim 1, wherein the electrode portion of the de-coupling capacitor comprises two second conductive bumps disposed at two sides of the decoupling capacitor.

7. The semiconductor package of claim 1, wherein the electrode portion of the de-coupling capacitor further comprises conductive layers contacting the second conductive bumps.

8. The semiconductor package of claim 1, wherein the at least one dielectric layer comprises a plurality of the dielectric layers, and the de-coupling capacitor further comprises a conductive layer disposed between the plurality of the dielectric layers.

9. The semiconductor package of claim 1, wherein the de-coupling capacitor is a multi-layer ceramic capacitor (MLCC).

10. The semiconductor package of claim 1, wherein the first and second conductive bumps include at least one selected from the group consisting of a metal, a metal alloy, a conductive metal oxide, a conductive polymer material, and a conductive complex material each selected from the group consisting of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C).

11. The semiconductor package of claim 1, further comprising:
a second substrate having a surface upon which at least one semiconductor chip is mounted, the second substrate being arranged under the first substrate, wherein the first and second substrates are connected to each other via the first and second conductive bumps.

12. The semiconductor package of claim 11, wherein the electrode portion of the de-coupling capacitor further comprises conductive layers contacting the second conductive bumps.

13. The semiconductor package of claim 11, further comprising:
at least one first conductive wire electrically connecting the at least one semiconductor chip on the first substrate to the first substrate; and
at least one second conductive wire electrically connecting the at least one semiconductor chip on the second substrate to the second substrate.

14. The semiconductor package of claim 1, further comprising:
a printed circuit board (PCB) connected to the first and second conductive bumps.

15. The semiconductor package of claim 14, wherein the second conductive bumps are connected to a power line and a ground line of the PCB.

16. A de-coupling capacitor comprising:
a plurality of conductive bumps configured to attach to a lower surface of a substrate; and
a dielectric layer between the plurality of conductive bumps.

17. A package on package, comprising:
a first substrate having an upper surface upon which at least one first semiconductor chip is mounted and a lower surface upon which at least one first solder ball is attached;
a second substrate on the first substrate, the second substrate including an upper surface upon which at least one second semiconductor chip is mounted and a lower surface upon which at least one second solder ball is attached, the at least one second solder ball being configured to electrically connect the first substrate to the second substrate; and
a de-coupling capacitor between the first and second substrates, the decoupling capacitor including an electrode portion and a dielectric layer, wherein the electrode portion includes conductive structures connected to at least one of ground lines and signal lines in the first and second substrates.

18. The POP of claim 17, wherein the conductive structures include an upper conductive pad electrically connected to one of a signal line and a ground line of the second substrate and a lower conductive pad connected to one of a signal line and a ground line of the first substrate and the dielectric layer is between the upper and lower conductive pads.

19. The POP of claim 18, further comprising:
a printed circuit board below the first substrate, wherein the at least one first solder ball is a plurality of first solder balls electrically connecting the first substrate to the printed circuit board.

20. The POP of claim 19, wherein the second substrate includes at least one of a ground line and a power line electrically connecting the plurality of first solder balls the upper conductive pad and the first substrate includes at least one of a ground line and a power line electrically connecting the plurality of first solder balls to the lower conductive pad.
